(19) United States
(12) Patent Application Publication
(10) Pub. No.: US 2011/0298955 A1
(43) Pub. Date: Dec. 8, 2011

(54) Clock multiplying circuit, solid-state imaging device, and phase-shift circuit

(75) Inventors: Satsuki Horimoto, Fukuoka (JP); Shunji Kawaguchi, Kanagawa (JP); Shizunori Matsumoto, Kanagawa (JP)

(73) Assignee: Sony Corporation, Tokyo (JP)

(21) Appl. No.: 13/064,912

(22) Filed: Apr. 26, 2011

(30) Foreign Application Priority Data
Jun. 4, 2010 (JP) 2010-128621
Sep. 1, 2010 (JP) 2010196145

(51) Int. Cl. H04N 5/335; H03H 11/22

(52) U.S. Cl. 348/308; 327/245; 348/E05.091

(57) ABSTRACT

A clock multiplying circuit includes: first and second inverters being ON/OFF-controlled by a positive- or negative-phase signal, respectively, of a first clock signal and including current source and current sync terminals; a capacitive element provided between output ends of the inverters; a current supplying unit increasing, if a frequency of the first clock signal increases, the control current and supplying the control current to the current source terminals of the inverters and outputting, from the current sync terminals of the inverters, a control current the same current amount as that of a control current to the current source terminal; a differential detecting unit receiving input of a potential difference signal between both electrodes of the capacitive element and generating a second clock signal having a phase difference of 90 degrees; and a multiplied-signal generating unit generating a double signal of the first clock signal on the basis of the clock signals.

### BACKGROUND OF THE INVENTION

1. Field of the Invention

The present invention relates to a circuit that multiplies a clock signal by two, a solid-stage imaging device including the circuit, and a phase-shift circuit for the clock signal.

2. Description of the Related Art

In the past, in various electronic apparatuses, clock signals have been used to control the operations of the electronic apparatuses. Examples of the control include operation control for a 2:1 parallel-to-serial conversion circuit or the like (see, for example, JP-A-2002-9629 (Patent Document 1)).

A schematic configuration of the 2:1 parallel-to-serial conversion circuit described in Patent Document 1 is shown in FIG. 4. The 2:1 parallel-to-serial conversion circuit shown in FIG. 4 is used for a circuit of a USB (Universal Serial Bus) interface or the like that converts parallel data into serial data and outputs the serial data.

A 2:1 parallel-to-serial conversion circuit 100 includes two flip-flop circuits for retiming 101 and 102 that convert input parallel data (PDIN1 and PDIN2) into a ½ frequency clock signal PCK. The 2:1 parallel-to-serial conversion circuit 100 includes a toggle flip-flop circuit 103 that generates a ½ frequency clock signal PCK from a reference clock signal CK. Further, the 2:1 parallel-to-serial conversion circuit 100 includes a selector 104 and a flip-flop circuit for serial conversion 105.

An output P1 of the flip-flop circuit for retiming 101, an output P2 of the flip-flop circuit for retiming 102, and the ½ frequency clock signal PCK are input to the selector 104. An output P3 of the selector 104 is output (SOUT in FIG. 4) to an external circuit through the flip-flop circuit for serial conversion 105.

The operation of the 2:1 parallel-to-serial conversion circuit 100 is explained below with reference to FIGS. 5A to 5H. FIGS. 5A to 5H are timing charts of the reference clock signal CK, the ½ frequency clock signal PCK, the input parallel data PDIN1 and PDIN2, and the output signals of the circuit units during the operation of the 2:1 parallel-to-serial conversion circuit 100. For all the operations of the units, a rising edge of the reference clock signal CK is set as a reference.

First, as shown in FIGS. 5A and 5B, the reference clock signal CK is divided into the ½ frequency clock signal PCK by the toggle flip-flop circuit 103. As shown in FIGS. 5E and 5F, the input parallel data (PDIN1 and PDIN2) are latched by the ½ frequency clock signal PCK and output respectively in the flip-flop circuits for retiming 101 and 102.

As shown in FIG. 5G, the selector 104 selects the output P1 of one flip-flop circuit for retiming 101 at timing when the ½ frequency clock signal PCK changes to a high level. The selector 104 selects the output P2 of the other flip-flop circuit for retiming 102 at timing when the ½ frequency clock signal PCK changes to a low level. The output P3 of the selector 104 is latched at the rising edge of the reference clock signal CK and output to the outside as SOUT (see FIG. 5H).

In the 2:1 parallel-to-serial conversion circuit 100 explained above, in order to maximize a setup/hold margin of timing for latching the output P3 of the selector 104 and a data changing point, it is desirable that a duty ratio of a clock signal is 50%. However, when fluctuation in a duty ratio of the reference clock signal CK is large, the setup/hold margin decreases. As a result, it is likely that an error occurs in output data.

As measures against such a problem, it is conceivable to adopt, for example, a method of once dividing the reference clock signal CK having fluctuation in the duty ratio by two and multiplying divided signals by two in a multiplying circuit to thereby align duty ratios of clock signals. As the multiplying circuit used in this case, various circuits have been proposed in the past (see, for example, JP-A-61-226669 (Patent Document 2)).

The configuration of a multiplying circuit proposed in Patent Document 2 is shown in FIG. 6. A multiplying circuit 200 proposed in Patent Document 2 includes an input signal inverter 201, two TTL (Transistor-transistor logic) gates 202 and 203, and three edge detectors 204 to 206. Further, the multiplying circuit 200 includes two detectors 207 and 208, a frequency divider 209, and integrating circuits (delay circuits) including resistors Ri and capacitors Ci (i=1 to 4). The input signal inverter 201, the three edge detectors 204 to 206, and the two detectors 207 and 208 include TTL gates. The circuit elements are wired and connected as appropriate to play predetermined functions.

The operation of the multiplying circuit 200 is explained with reference to FIGS. 7A to 7J. FIGS. 7A to 7J are timing charts of output signals of the circuit elements during the operation of the multiplying circuit 200. Waveforms of output signals of the circuit elements (corresponding to output signals at “a” to “f” points in FIG. 6) are shown.

First, when a signal is input to an input end (the “a” point) of the input signal inverter 201, the input signal inverter 201 inverts and outputs the input signal (see FIGS. 7A and 7B). Subsequently, as shown in FIG. 7C, the frequency divider 209 divides a signal phase-inverted by the input signal inverter 201 into a ½ frequency and outputs the divided signal. Thereafter, the divided signal output from the frequency divider 209 passes through an integrating circuit including a resistor R1 and a capacitor C1 having a time constant larger than a period T of the input signal and changes to a signal waveform of a triangular wave shape (see FIG. 7D).

This signal of the triangular wave shape (hereinafter referred to as triangular wave signal) is input to a plus terminal (a positive-phase terminal) of the detector 208. The triangular wave signal passes through an integrating circuit including a resistor R2 and a capacitor C2 having a time constant sufficiently larger than the period T. As shown in FIG. 7E, a signal having a fixed level (hereinafter referred to as threshold signal) is output from the integrating circuit. The threshold signal is input to a minus terminal (an inverse phase terminal) of the detector 208.

When the level of the triangular wave signal is equal to or higher than the level of the threshold signal, the detector 208 outputs a high-level signal. When the level of the triangular wave signal is lower than the level of the threshold signal, the detector 208 outputs a low-level signal. As a result, as shown in FIG. 7F, a signal phase-shifted 90 degrees with respect to the divided signal (FIG. 7C) output from the frequency divider 209 is output from the detector 208.

As shown in FIG. 7G, the edge detector 204 outputs a pulse-like signal with reference to a falling edge of the signal (FIG. 7F) output from the detector 208. As shown in FIG. 7H, the edge detector 205 outputs a pulse-like signal with reference to a rising edge of the signal output from the detector 208. Further, as shown in FIG. 7I, the edge detector 206 outputs a pulse-like signal with reference to a falling edge of the inverted signal (FIG. 7B) output from the input signal inverter 201.

In the multiplying circuit 200 described in Patent Document 2, the detector 207 outputs a pulse-like signal with reference to rising edges of the pulse-like signals output from the three edge detectors 204 to 206. As a result, as shown in FIG. 7J, the detector 207 outputs a signal obtained by multiplying the input signal (FIG. 7A) by two.

### SUMMARY OF THE INVENTION

As explained above, as the multiplying circuit used in aligning duty ratios of clock signals, for example, the multiplying circuit employing the integrating circuits (the delay circuits) including the resistors and the capacitors proposed in Patent Document 2 or the like can be applied. However, when the multiplying circuit having the configuration proposed in Patent Document 2 or the like is used, there are problems explained below.

In the multiplying circuit 200 (FIG. 6) described in Patent Document 2, as explained above, a phase-shifted divided clock signal is generated using the triangular wave signal output from the integrating circuit (the delay circuit) including the resistor R1 and the capacitor C1. In such a circuit, if the integrating circuit is set to make the gradient of the level of the triangular wave signal gentle to correspond to a low-frequency operation, the amplitude of the triangular wave signal decreases when the circuit operates at a high frequency. In this case, it is difficult to compare the triangular wave signal (FIG. 7D) and the threshold signal (FIG. 7E) in the detector 208.

In this case, since the amplitude of the triangular wave signal is small, the triangular wave signal tends to be affected by input fluctuation of the reference clock signal CK. Further, the level of the threshold signal compared with the triangular wave signal is also affected by the input fluctuation of the reference clock signal CK. The gradient (the amplitude) of the triangular wave signal and the level of the threshold signal also fluctuate according to fluctuation in performance of the resistor and the capacitor included in the integrated circuit.

In short, in the multiplying circuit 200 employing the integrated circuits (the delay circuits) proposed in Patent Document 2, because of the various causes explained above, it is difficult to stably generate a double clock signal with a predetermined duty ratio (e.g., 50%) when a frequency changes. As a result, in the multiplying circuit 200 proposed in Patent Document 2 or the like, it is difficult to sufficiently deal with a frequency change of an input clock signal.

Therefore, it is desirable to provide a clock multiplying circuit, a solid-state imaging device including the clock multiplying circuit, and a phase-shift circuit that can accurately obtain a clock signal with a desired duty ratio even if an operating frequency substantially fluctuates.

According to an embodiment of the present invention, there is provided a clock multiplying circuit including a first inverter, a second inverter, a capacitive element, a current supplying unit, a differential detecting unit, and a multiplied-signal generating unit. The configurations and the functions of the units are as explained below. The first inverter is ON/OFF-controlled by a positive-phase signal of a first clock signal and includes a current source terminal and a current sync terminal for a control current flowing on the inside when the first inverter is on. The second inverter is ON/OFF-controlled by a negative-phase signal of the first clock signal and includes a current source terminal and a current sync terminal for a control current flowing on the inside when the second inverter is on. The current source terminal and the current sync terminal of the second inverter are respectively connected to the current source terminal and the current sync terminal of the first inverter. The capacitive element is provided between an output end of the first inverter and an output end of the second inverter. The current supplying unit increases, if the frequency of the first clock signal increases, the control current and supplies the control current to the current source terminals of the first inverter and the second inverter. The current supplying unit outputs, from the current sync terminals of the first inverter and the second inverter, a control current having a current amount same as a current amount of the control current supplied to the current source terminal. The differential detecting unit receives input of a potential difference signal between both electrodes of the capacitive element and generates, on the basis of a comparison result in a median value of a fluctuation range of the potential difference signal, a second clock signal having a phase difference of 90 degrees with respect to the positive-phase signal of the first clock signal. The multiplied-signal generating unit generates a double signal of the first clock signal on the basis of the first clock signal and the second clock signal.

According to another embodiment of the present invention, there is provided a solid-state imaging device including plural pixels arranged in a matrix shape in a row direction and a column direction, the clock multiplying circuit according to the embodiment explained above, a digital-to-analog conversion circuit, and an analog-to-digital conversion circuit. In the solid-state imaging device, the digital-to-analog conversion circuit is driven by a double signal generated by the clock multiplying circuit and generates a reference voltage signal for analog-to-digital conversion. The analog-to-digital conversion circuit includes a counter unit driven by the double signal generated by the clock multiplying signal and converts a pixel value of the pixels into a digital value.

According to still another embodiment of the present invention, there is provided a phase-shift circuit including the first inverter, the second inverter, the capacitive element, the current supplying unit, and the differential detecting unit in the clock multiplying circuit according to the embodiment explained above.

In the embodiments, the first and second inverters are ON/OFF-controlled by the first clock signal, whereby the direction of the control current (a bias current) supplied from the current supplying unit to the capacitive element via the first and second inverters is repeatedly changed. When the direction of the control current is repeatedly changed, a potential difference signal between both the electrodes of the capacitive element is input to the differential detecting unit. Subsequently, the differential detecting unit generates, on the basis of a comparison result in a median value of a fluctuation range of the input potential difference signal, the second clock signal having a phase difference of 90 degrees with respect to the positive-phase signal of the first clock signal. In the embodiments, the multiplied-signal generating unit generates a double signal of the first clock signal on the basis of the first clock signal and the second clock signal.

In the embodiments, when the double signal is generated in the operation, if the frequency of the first clock signal increases, the control current supplied to the first and second inverters is increased. Consequently, even if the frequency of the first clock signal increases, the amplitude of the potential difference signal between both the electrodes of the capacitive element can be set sufficiently large. Output accuracy of a comparison result in a median value of a fluctuation range of a potential difference signal in the differential detecting unit can be improved. Further, the differential detecting unit generates the second clock signal on the basis of a comparison result in a median value of a fluctuation range of the input potential signal. Therefore, irrespective of a change in the frequency of the first clock signal, the second clock signal can be stably and highly accurately generated.

As explained above, in the multiplying circuit according to the embodiment, even if the frequency of an input clock signal changes, a potential difference signal between both the electrodes of the capacitive element detected by the differential detecting unit can be set sufficiently large. In the embodiments, irrespective of a change in the frequency of the input clock signal, the clock signal having a phase difference of 90 degrees with respect to the positive-phase signal of the first clock signal can be stably and highly accurately generated. Therefore, in the embodiments, even if the frequency of the input clock signal changes, a double clock signal with a duty ratio of 50% can be accurately generated.

Further, as explained later, in the embodiments, a duty ratio of the second clock signal having a phase difference of 90 degrees with respect to the positive-phase signal of the first clock signal can also be accurately adjusted to 50%. Therefore, in the phase-shift circuit according to the embodiment, the second clock signal with the accurately-adjusted duty ratio can be supplied to an external circuit.

In short, with the clock multiplying circuit, the solid-state imaging device including the clock multiplying circuit, and the phase-shift circuit, even if an operating frequency substantially fluctuates, a clock signal highly-accurately adjusted to a desired duty ratio can be supplied to the external circuit.

### BRIEF DESCRIPTION OF THE DRAWINGS

FIG. 1 is a circuit diagram of a multiplying circuit according to an embodiment of the present invention;

FIGS. 2A to 2I are timing charts during the operation of the multiplying circuit according to the embodiment of the present invention;

FIG. 3 is a diagram of a configuration example of a solid-state imaging device including the multiplying circuit according to the embodiment of the present invention;

FIG. 4 is a block diagram of a 2:1 parallel-to-serial conversion circuit in the past;

FIGS. 5A to 5H are timing charts during the operation of the 2:1 parallel-to-serial conversion circuit in the past;

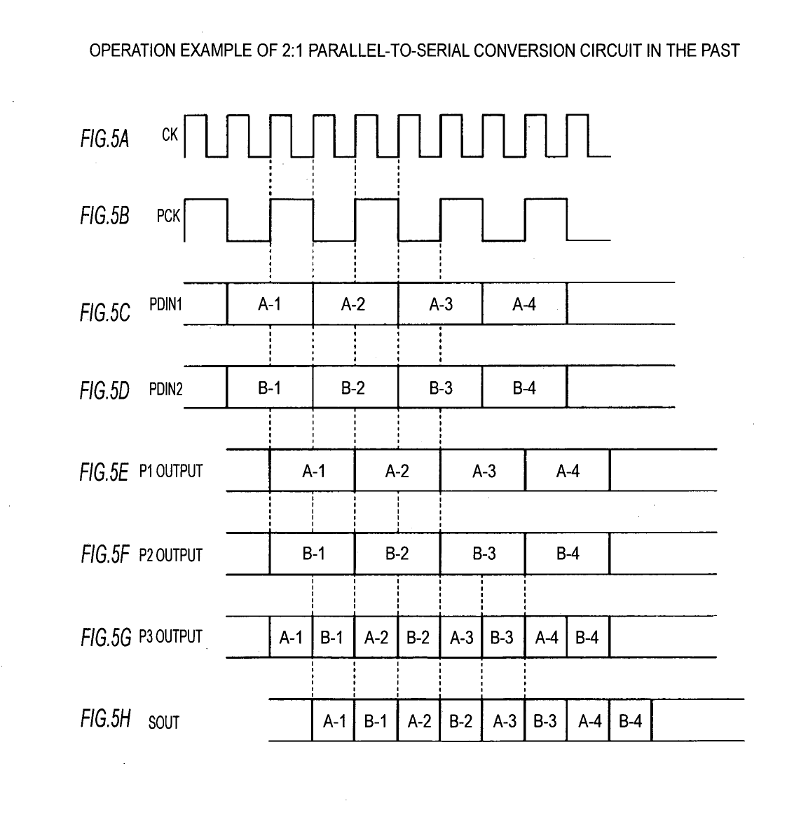

FIG. 6 is a circuit diagram of a multiplying circuit in the past; and

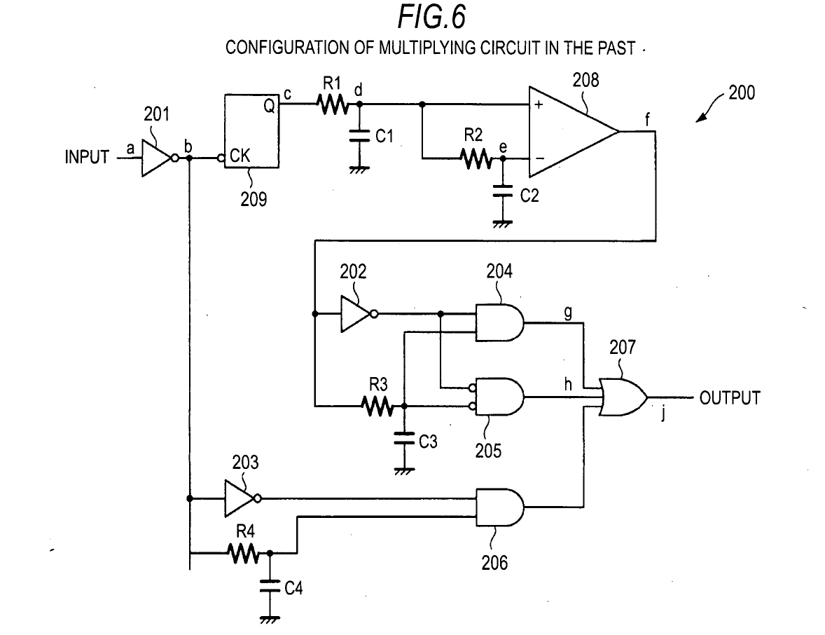

FIGS. 7A to 7J are timing charts during the operation of the multiplying circuit in the past.

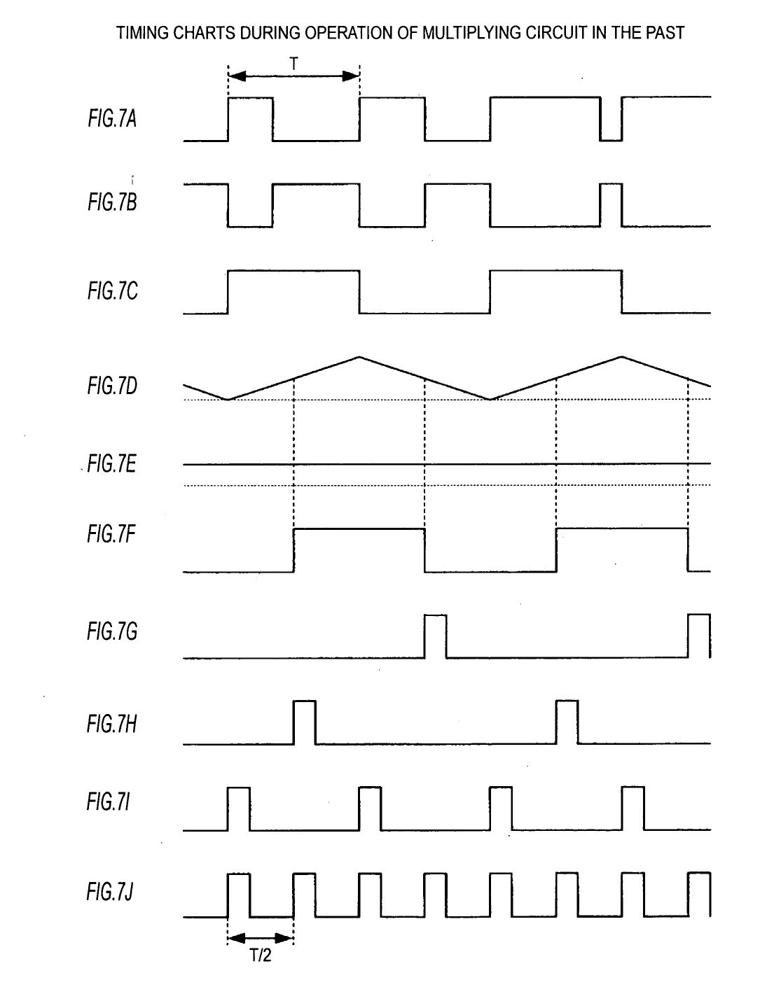

### DESCRIPTION OF THE PREFERRED EMBODIMENTS

Examples of a multiplying circuit, a phase-shift circuit, and a solid-state imaging device including the multiplying circuit according to an embodiment of the present invention are explained in the following order with reference to the accompanying drawings. The present invention is not limited to the example explained below.

1. Configuration example of the multiplying circuit

2. Operation example of the multiplying circuit

3. Configuration example of the solid-state imaging device

### <1. Configuration Example of the Multiplying Circuit>

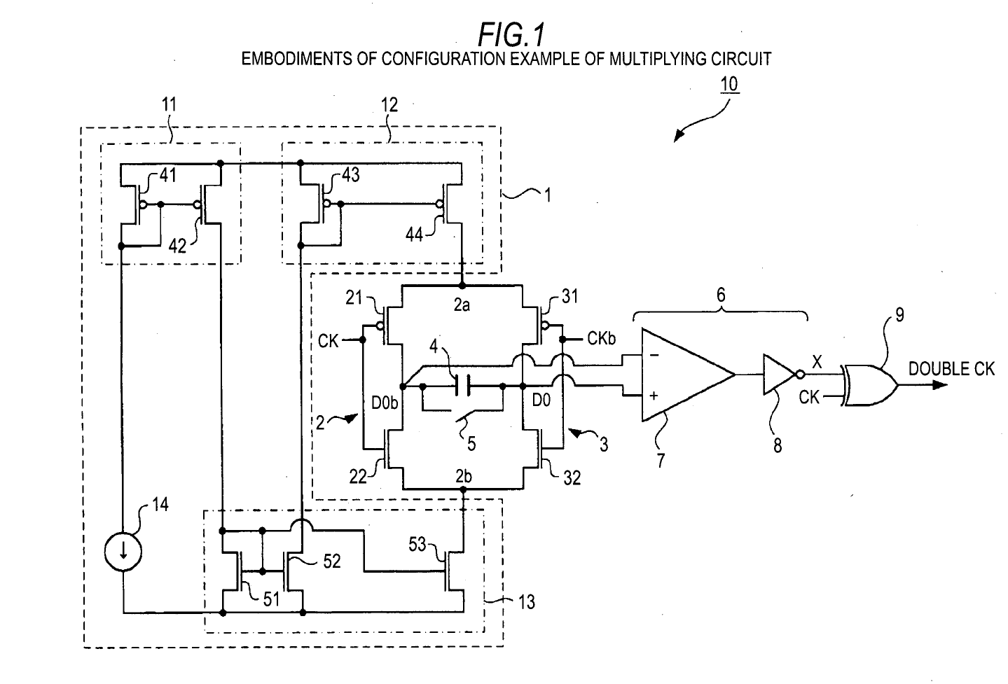

A schematic configuration of the multiplying circuit according to the embodiment of the present invention is shown in FIG. 1. A multiplying circuit 10 (a clock multiplying circuit) includes a current supplying unit 1, a first inverter 2, a second inverter 3, a capacitive element 4, an initializing switch 5 (an initializing switch element), a differential detector 6, and an EXOR (exclusive OR) element 9 (a multiplied-signal generating unit).

The current supplying unit 1 includes a first current mirror circuit 11, a second current mirror circuit 12, a third current mirror circuit 13, and a variable bias current source (a variable current source).

The first current mirror circuit 11 includes a first PMOS (Positive channel Metal Oxide Semiconductor) transistor 41 and a second PMOS transistor 42. A source terminal of the first PMOS transistor 41 is connected to a source terminal of the second PMOS transistor 42. A gate terminal of the first PMOS transistor 41 is connected to a gate terminal of the second PMOS transistor 42 and a drain terminal of the first PMOS transistor 41. The drain terminal of the first PMOS transistor 41 is connected to a terminal on a current source side of the variable bias current source 14. A drain terminal of the second PMOS transistor 42 is connected to a drain terminal of a first NMOS (Negative channel Metal Oxide Semiconductor) transistor 51 explained later in the third current mirror circuit 13.

The second current mirror circuit 12 includes a third PMOS transistor 43 and a fourth PMOS transistor 44. A source terminal of the third PMOS transistor 43 is connected to a source terminal of the fourth PMOS transistor 44 and a source terminal of the first PMOS transistor 41 (the second PMOS transistor 42) in the first current mirror circuit 11. A gate terminal of the third PMOS transistor 43 is connected to a gate terminal of the fourth PMOS transistor 44 and a drain terminal of the third PMOS transistor 43. The drain terminal of the third PMOS transistor 43 is connected to a drain terminal of a second NMOS transistor 52 explained later in the third current mirror circuit 13. A drain terminal of the fourth PMOS transistor 44 is connected to a current source terminal 2a of the first inverter 2 and the second inverter 3.

The third current mirror circuit 13 includes the NMOS transistor 51, the second NMOS transistor 52, and a third NMOS transistor 53. The drain terminal of the first NMOS transistor 51 is connected to the drain terminal of the second PMOS transistor 42 in the first current mirror circuit 11. A gate terminal of the first NMOS transistor 51 is connected to a gate terminal of the second NMOS transistor 52, a gate terminal of the third NMOS transistor 53, and the drain terminal of the first NMOS transistor 51. A source terminal of the first NMOS transistor 51 is connected to a source terminal of the second NMOS transistor 52, a source terminal of the third NMOS transistor 53, and a terminal on a current sync side of the variable bias current source 14. The drain terminal of the second NMOS transistor 52 is connected to the drain terminal of the third PMOS transistor 43 in the second current mirror circuit 12. A drain terminal of the third NMOS transistor 53 is connected to a current sync terminal 2b of the first inverter 2 and the second inverter 3.

The variable bias current source 14 supplies predetermined bias current (a control current) to the first inverter 2 and the second inverter 3 via the first to third current mirror circuits 11 to 13. In this embodiment, as the variable bias current source 14, a variable current source that can adjust a bias current according to an operating frequency of the multiplying circuit 10 (the frequency of a clock signal CK input from the outside) is used. Specifically, the variable bias current source 14 operates to increase and supply the bias current when the frequency of the input clock signal CK increases and reduce and supply the bias current when the frequency of the clock signal CK decreases. As the variable bias current source 14, any variable bias current source can be used as long as the variable bias current source has a bias current adjusting function explained above.

In the current mirror circuits, amounts of electric currents flowing on an input side thereof are the same as those of electric currents flowing on an output side. Therefore, by configuring the current supplying unit 1 as explained above, a current amount flowing into the current source terminal 2a of the first inverter 2 and the second inverter 3 and a current amount flowing out from the current sync terminal 2b can be set the same. As a result, as explained later, a clock signal with a duty ratio of 50% (a clock signal phase-shifted 90 degrees with respect to a double clock signal and the input clock signal CK) can be more surely and highly accurately generated even if an operating frequency substantially fluctuates.

The first inverter 2 includes a PMOS transistor 21 and an NMOS transistor 22. A source terminal of the PMOS transistor 21 is connected to the current source terminal 2a. A drain terminal of the PMOS transistor 21 is connected to a drain terminal of the NMOS transistor 22. A connection point between both the transistors is an output terminal D0b (an output end) of the first inverter 2. A source terminal of the NMOS transistor 22 is connected to the current sync terminal 2b. A gate terminal of the PMOS transistor 21 is connected to a gate terminal of the NMOS transistor 22. A positive-phase clock signal CK (a first clock signal) is input to both the gate terminals from the outside. In other words, ON/OFF operations of the PMOS transistor 21 and the NMOS transistor 22 included in the first inverter 2 are controlled by the positive-phase clock signal CK.

The second inverter 3 includes a PMOS transistor 31 and an NMOS transistor 32. A source terminal of the PMOS transistor 31 is connected to the current source terminal 2a. A drain terminal of the PMOS transistor 31 is connected to a drain terminal of the NMOS transistor 32. A connection point between both the transistors is an output terminal D0 (an output end) of the second inverter 3. A source terminal of the NMOS transistor 32 is connected to the current sync terminal 2b. A gate terminal of the PMOS transistor 31 is connected to a gate terminal of the NMOS transistor 32. A negative-phase clock signal CKb is input to both the gate terminals from the outside. In other words, ON/OFF operations of the PMOS transistor 31 and the NMOS transistor 32 included in the second inverter 3 are controlled by the negative-phase clock signal CKb.

The capacitive element 4 is provided between the output terminal D0b of the first inverter 2 and the output terminal D0 of the second inverter 3. When the capacitive element 4 is connected in this way, the MOS transistors in the first inverter 2 and the second inverter 3 are ON/OFF-controlled by a clock signal, whereby the direction of a bias current supplied from the current supplying unit 1 to the capacitive element 4 is repeatedly inverted. A voltage signal of the output terminal D0b of the first inverter 2, which changes when the direction of the bias current is inverted, is output to a minus side terminal of a differential comparator 7 explained later. A voltage signal of the output terminal D0 of the second inverter 3, which changes when the direction of the bias current is inverted, is output to a plus side terminal of the differential comparator 7 explained later.

The initializing switch 5 is provided between both electrodes of the capacitive element 4. When the multiplying circuit 10 performs multiplication processing for a clock signal, first, the initializing switch 5 is turned on and a potential difference between both the electrodes of the capacitive element 4, i.e., a potential difference between the output terminal D0b of the first inverter 2 and the output terminal D0 of the second inverter 3 is set to zero.

The differential detector 6 includes the differential comparator 7 and a third inverter 8 provided at an output end of the differential comparator 7.

The differential comparator 7 calculates a difference signal (a phase difference signal) between an output signal (a voltage signal) of the second inverter 3 input to a plus side terminal of the differential comparator 7 and an output signal (a voltage signal) of the first inverter 2 input to a minus side terminal of the differential comparator 7. The differential comparator 7 outputs, from the calculated difference signal, a comparison result in a median value of a fluctuation range of the difference signal.

Specifically, the differential comparator 7 outputs a low-level signal when the level of the difference signal is equal to or higher than the median value and outputs a high-level signal when the level of the difference signal is lower than the median value. As a result, as explained later, the differential comparator 7 generates a clock signal (a third clock signal) phase-shifted 90 degrees with respect to the negative-phase clock signal CKb input to the second inverter 3. The differential comparator 7 outputs the generated clock signal to the third inverter 8.

The median value of the difference signal can be set on the basis of the potential at the output terminal D0 or D0b in an initial state.

The third inverter 8 inverts the clock signal input from the differential comparator 7. Consequently, a clock signal X (a second clock signal) phase-shifted 90 degrees with respect to the positive-phase clock signal CK input to the first inverter 2 is generated. The third inverter 8 outputs the generated clock signal X to one input terminal of the EXOR element 9.

The EXOR element 9 calculates exclusive OR of the clock signal X input to one input terminal from the third inverter 8 and the positive-phase clock signal CK input to the other input terminal and outputs a calculated signal of the exclusive OR. As a result, a double clock signal (a double signal) of the positive-phase clock signal is output from the EXOR element 9.

### <2. Operation Example of the Multiplying Circuit>

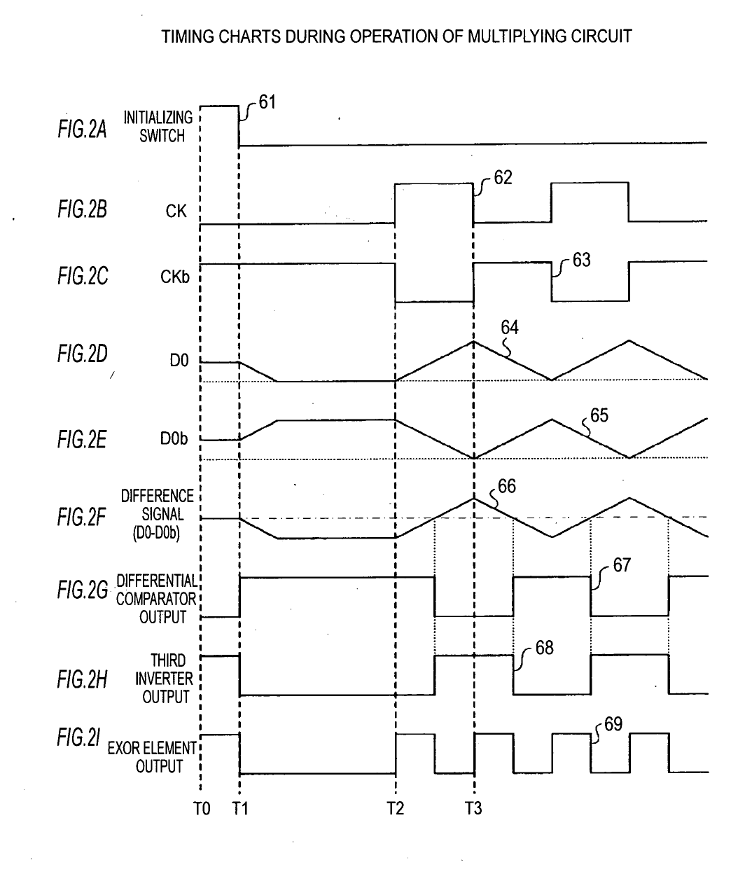

A specific operation of the multiplying circuit 10 according to this embodiment is explained below with reference to FIGS. 2A to 2I. FIGS. 2A to 2I are timing chart of a clock signal input to the multiplying circuit 10 and signals output from the circuit elements included in the multiplying circuit 10. More specifically, FIG. 2A is an operation waveform chart of the initializing switch 5. FIGS. 2B and 2C are respectively signal waveform charts of the positive-phase clock signal CK and the negative-phase clock signal CKb input to the multiplying circuit 10. FIGS. 2D and 2E are respectively output signal waveform charts (voltage, signal waveform chart) at the output terminal D0 of the second inverter 3 and the output terminal D0b of the first inverter 2. FIG. 2F is a waveform chart of a difference signal of an output signal of the second inverter 3 and an output signal of the first inverter 2, i.e., a difference signal generated by the differential comparator 7. FIG. 2G is a waveform chart of an output signal of the differential comparator 7. FIGS. 2H and 2I are respectively waveform charts of output signals of the third inverter 8 and the EXOR element 9.

First, at multiplication processing start time T0, the initializing switch 5 is turned on and thereafter maintains the ON state until time T1 (see a signal waveform 61 of FIG. 2A). Between time T0 and time T1, the potentials at the output terminal D0b of the first inverter 2 and the output terminal D0 of the second inverter 3 are the same. Therefore, difference signal 66 (a value (a potential difference) of FIG. 2F) generated by the differential comparator 7 is initialized to zero. As a result, in an initial state, a high-level signal is output from the multiplying circuit 10 (the EXOR element 9) (see FIG. 2I).

In the operation example explained here, as shown in FIGS. 2D and 2E, the potential at the output terminal. D0 typically changes in anti-phase to the potential at the output terminal D0b. Therefore, a median value in a fluctuation range of a difference signal 66 is a potential level difference between the output terminals D0 and D0b in the initial state. In other words, irrespective of the influence of, for example, fluctuation in a threshold voltage of a transistor or fluctuation in a driving ability at the output terminal D0b of the first inverter 2 and the output terminal D0 of the second inverter 3, an output of the differential comparator 7 is typically inverted at the median value of the fluctuation range of the difference signal 66.

Subsequently, from time T1 to time T2 when the level of the positive-phase clock signal CK changes to the high level, the PMOS transistor 31 of the second inverter 3 is in an OFF state and the NMOS transistor 32 is in the ON state. Therefore, a bias current flows out from the output terminal D0. As a result, as shown in FIG. 2D, the potential at the output terminal D0 of the second inverter 3 linearly drops. On the other hand, between time T1 and time T2, the PMOS transistor 21 of the first inverter 2 is in the ON state and the NMOS transistor 22 is in the OFF state. Therefore, a bias current flows into the output terminal D0b. As a result, as shown in FIG. 2E, the potential of the output terminal D0b of the first inverter 2 linearly rises.

Subsequently, at time T2, when the positive-phase clock signal CK changes to the high level (the negative-phase clock signal CKb changes to the low level), the PMOS transistor 31 of the second inverter 3 changes to the ON state and the NMOS transistor 32 changes to the OFF state. Consequently, a bias current flows into the output terminal D0 of the second inverter 3. Therefore, as shown in FIG. 2D, the potential at the output terminal D0 linearly rises after time T2. At this point, the PMOS transistor 21 of the first inverter 2 changes to the OFF state and the NMOS transistor 22 changes to the ON state. As a result, a bias current flows out from the output terminal D0b of the first inverter 2. Therefore, as shown in FIG. 2E, the potential at the output terminal D0b linearly drops after time T2.

At time T3, when the positive-phase clock signal CK changes to the low level (the negative-phase clock signal CKb changes to the high level), the PMOS transistor 31 of the second inverter 3 changes to the OFF state and the NMOS transistor 32 changes to the ON state. Consequently, a bias current flows out from the output terminal D0 of the second inverter 3. Therefore, as shown in FIG. 2D, the potential of the output terminal D0 linearly drops after time T3. At this point, the PMOS transistor 21 of the first inverter 2 changes to the ON state and the NMOS transistor 22 changes to the OFF state. As a result, a bias current flows into the output terminal D0b of the first inverter 2. Therefore, as shown in FIG. 2E, the potential at the output terminal D0b linearly rises after time T3.

After time T3, the potentials at the output terminals of the inverters repeat rise and drop at a half period interval of a clock signal. As a result, as shown in FIGS. 2D and 2E, the potentials at the output terminal D0 of the second inverter 3 and the output terminal D0b of the first inverter 2 change in a triangular wave shape. In this embodiment, since the current supplying unit 1 includes plural current mirror circuits, a current amount of a bias current supplied to the circuit including the first inverter 2 and the second inverter 3 and a current amount of a bias current drawn out (output) from the circuit are the same. Therefore, the speed of charging and discharging operations in the capacitive element 4 is fixed. As shown in FIGS. 2D and 2E, an output signal 64 of the output terminal D0 of the second inverter 3 and an output signal 65 of the output terminal D0b of the first inverter 2 change symmetrically with respect to a time axis. Consequently, a median value of a difference signal of both the output signals is also fixed.

When the output signals of the second inverter 3 and the first inverter 2 explained above are input to the differential comparator 7, the differential comparator 7 generates a difference signal of the output signal of the second inverter 3 and the output signal of the first inverter 2. When the difference signal is generated, the output signal of the second inverter 3 and the output signal of the first inverter 2 are, output signals of a triangular wave shape that symmetrically change each other with respect to the time axis. Therefore, as shown in FIG. 2F, the difference signal 66 is also a signal waveform of a triangular wave shape.

The differential comparator 7 outputs a comparison result in a median value of a fluctuation range of the generated difference signal 66. Specifically, the differential comparator 7 outputs a low-level signal when the level of the difference signal 66 is equal to or higher than the median value and outputs a high-level signal when the level of the difference signal 66 is lower than the median value. As a result, as shown in FIG. 2G, the differential comparator 7 generates a clock signal 67 with a duty ratio of 50% having a phase difference of 90 degrees with respect to the negative-phase clock signal CKb (a signal 63 in FIG. 2C). The differential comparator 7 outputs the clock signal 67 phase-shifted (delayed) 90 degrees with respect to the negative-phase clock signal CKb to the third inverter 8.

Subsequently, the third inverter 8 inverts the clock signal 67 input from the differential comparator 7 and outputs an inverted signal of the clock signal 67 to the EXOR element 9. Since the third inverter 8 inverts an output signal of the differential comparator 7, as shown in FIG. 2H, the third inverter 8 outputs a clock signal 68 phase-shifted (delayed)90 degrees with respect to the positive-phase clock signal CK (a signal 62 in FIG. 2B). In other words, a circuit unit from the current supplying unit 1 to the differential detector 6 in the multiplying circuit 10 according to this embodiment also functions as a phase shift circuit that shifts the phase of the input positive-phase clock signal CK.

The EXOR element 9 calculates exclusive OR of the positive-phase clock signal CK (the signal 62 in FIG. 2B) and the clock signal 68 phase-shifted 90 degrees with respect to the positive-phase clock signal CK output from the third inverter 8. In other words, the EXOR element 9 outputs a low-level signal in a period in which both the levels of the input two clock signals are the high level or the low level and otherwise outputs a high-level signal. As a result, as shown in FIG. 2I, the EXOR element 9 outputs a double clock signal 69, a clock period of which is a half of that of the input clock signals and a duty ratio of which is 50%.

As explained above, the multiplying circuit 10 according to this embodiment generates the double clock signal 69 with a duty ratio of 50%.

In the multiplying circuit 10 according to this embodiment, when a bias current supplied to the first inverter 2 and the second inverter 3 is fixed, the gradient of a triangular wave signal (the difference signal 66 of FIG. 2F) calculated by the differential comparator 7 is fixed. Therefore, in the multiplying circuit 10 according to this embodiment, when the bias current supplied to the first inverter 2 and the second inverter 3 is fixed, if the frequency of the input clock signal CK increases, the amplitude of the difference signal 66 (the triangular wave signal) calculated by the differential comparator 7 decreases. In this case, detection accuracy of a comparison result in a median value of a fluctuation range of the difference signal 66 in the differential comparator 7 falls.

However, in this embodiment, when the operating frequency rises, the bias current supplied from the current supplying unit 1 to the first inverter 2 and the second inverter 3 is increased. In this case, the gradient of the triangular wave signal calculated by the differential comparator 7 increases and the amplitude of the triangular wave signal also increases. As a result, the detection accuracy of the comparison result in the median value of the fluctuation range of the difference signal 66 in the differential comparator 7 is improved. A clock signal with a duty ratio of 50% having a phase difference of 90 degrees with respect to the input clock signal CK can be stably and accurately generated. Therefore, in this embodiment, a double clock signal with a duty ratio of 50%, which is finally generated, can be stably and highly accurately generated.

On the other hand, when the operating frequency is low, in this embodiment, the bias current supplied to the first inverter 2 and the second inverter 3 is reduced. In this case, the gradient of the triangular wave signal calculated by the differential comparator 7 decreases. However, since a low-level period or a high-level period of a clock signal increases, the amplitude of the triangular wave signal is sufficiently large. Therefore, in this embodiment, even if the bias current is reduced when the operating frequency is low, the detection accuracy of the comparison result in the median value in the fluctuation range of the triangular wave signal (the difference signal) in the differential comparator 7 does not fall. Further, power consumption in the multiplying circuit 10 can be reduced by reducing the bias current when the operating frequency is low.

In this embodiment, as explained above, the bias current supplied to the circuit including the first inverter 2 and the second inverter 3 by the current supplying unit 1 and a bias current drawn out from the circuit are controlled to be the same. Therefore, in this embodiment, irrespective of the frequency of the input clock signal CK, as shown in FIGS. 2D and 2E, an output signal at the output terminal D0 of the second inverter 3 and an output signal at the output terminal D0b of the first inverter 2 change symmetrically with respect to the time axis. As a result, when the differential comparator 7 generates a clock signal phase-shifted 90 degrees, an output of the differential comparator 7 is inverted at the median value of the fluctuation range of the differential signal 66. In other words, the output of the differential comparator 7 is typically inverted at the median value of the fluctuation range of the difference signal 66 irrespective of the frequency of the clock signal CK. Therefore, it is possible to more stably generate a double clock signal with a duty ratio of 50%.

Consequently, the multiplying circuit 10 according to this embodiment can accurately and stably obtain a clock signal with a duty ratio of 50% irrespective of fluctuation in an operating frequency of the multiplying circuit 10.

In the multiplying circuit 10 according to this embodiment, a clock signal with a duty ratio of 50% having a phase difference of 90 degrees with respect to the input clock signal CK can be stably and accurately output from the third inverter 8. Therefore, the multiplying circuit 10 according to this embodiment can supply a clock signal, a duty ratio of which is highly accurately adjusted to 50%, to an external circuit that needs a clock signal phase-shifted 90 degrees with respect to the input clock signal CK.

In the example explained in this embodiment, the differential detector 6 includes the differential comparator 7 and the third inverter 8, whereby a clock signal phase-shifted 90 degrees with respect to the positive-phase clock signal CK is generated from the differential detector 6. However, the present invention is not limited to this.

For example, when the output terminal D0b of the first inverter 2 and the output terminal D0 of the second inverter 3 are respectively connected to a plus terminal and a minus terminal of the differential comparator 7, a positive-phase clock signal phase-shifted 90 degrees can be directly output from the differential comparator 7. In this case, the differential detector 6 can include only the differential comparator 7.

For example, when the negative-phase clock signal CKb is input to the first inverter 2 and the positive-phase clock signal CK is input to the second inverter 3, as in the case explained above, a positive-phase clock signal phase-shifted 90 degrees can be directly output from the differential comparator 7. The differential detector 6 can include only the differential comparator 7.

When the differential detector 6 includes only the differential comparator 7 as explained above, the circuit configuration of the multiplying circuit 10 can be further simplified. However, when a waveform of an output signal of the differential comparator 7 dulls, as in the multiplying circuit 10 according to this embodiment, in order to sharpen the waveform of the output signal of the differential comparator 7, it is desirable to provide the third inverter 8 on the output side of the differential comparator 7.

### <3. Configuration Example of the Solid-State Imaging Device>

An example in which the multiplying circuit 10 according to the embodiment of the present invention shown in FIG. 1 is applied to a solid-state imaging device such as a CMOS (Complementary Metal-Oxide Semiconductor) image sensor is explained below. In such a solid-state imaging device, in order to generate a high-definition and high-frame rate video signal, circuits such as a counter and a DAC (Digital to Analog Converter) are often driven in a DDR (Double Data Rate) system.

When the counter and the DAC are driven in the DDR system, since input data is latched during a rising edge and a falling edge of a clock signal, it is desirable that a duty ratio of the clock signal is 50% taking into account an operation margin of the clock signal. Therefore, in such an application, the multiplying circuit 10 according to the embodiment of the present invention shown in FIG. 1 is suitable as a clock supply source.

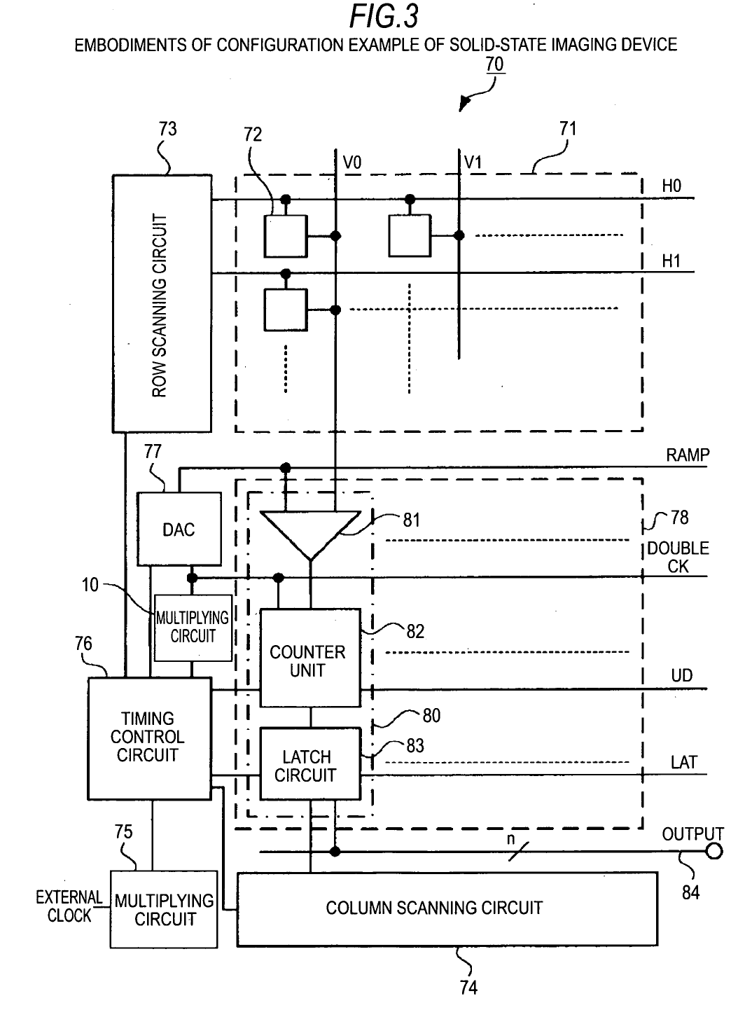

A circuit configuration near the multiplying circuit 10 in a CMOS solid-state imaging device is shown in FIG. 3.

A solid-state imaging device 70 includes a pixel array unit 71 in which plural pixels 72 are arranged in a matrix shape in a row direction and a column direction, a row scanning circuit 73, a column scanning circuit 74, two multiplying circuits 10 and 75, and a timing control circuit 76. The solid-state imaging device 70 further includes a DAC 77 (a digital-to-analog conversion circuit) and an ADC (Analog to Digital Converter) block 78. The configurations and the functions of the units are as explained below.

The pixels 72 in the pixel array unit 71 are connected to row selection lines Hi and column signal lines Vj (i, j=0, 1, 2, . . . ) corresponding thereto. The row scanning circuit 73 selects a predetermined row selection line Hi for reading a pixel value out of the plural row selection lines Hi (i=0, 1, 2, . . . ). The column scanning circuit 74 selects a predetermined column signal line Vj (j=0, 1, 2, . . . ) for reading out a pixel value in the row selection line Hi selected by the row scanning circuit 73.

The multiplying circuit 75 multiplies a clock signal input from the outside and generates a reference clock signal. The multiplying circuit 75 outputs the generated reference clock signal to the timing control circuit 76.

The timing control circuit 76 generates an internal clock signal using the reference clock signal input from the multiplying circuit 75. The timing control circuit 76 outputs the generated internal clock signal to the row scanning circuit 73, the column scanning circuit 74, the DAC 77, the ADC block 78, and the multiplying circuit 10.

The multiplying circuit 10 includes the multiplying circuit according to the embodiment of the present invention explained with reference to FIGS. 1 and 2. The multiplying circuit 10 multiplies the internal clock signal input from the timing control circuit 76 and generates a double clock signal with a duty ratio of 50%. The multiplying circuit 10 outputs the generated double clock signal with a duty ratio of 50% to the DAC 77 and a counter unit 82 in a column ADC unit 80.

The DAC 77 generates a reference voltage RAMP for analog to digital conversion and supplies the reference voltage RAMP to the ADC block 78. In this example, the DAC 77 is DDR-driven by the double clock signal with a duty ratio of 50% input from the multiplying circuit 10.

The ADC block 78 includes plural column ADC units 80 (analog-to-digital conversion circuits). The column ADC units 80 are provided in columns of the pixel array unit 71 corresponding thereto. Each of the column ADC units 80 includes a comparator 81, a counter unit 82, and a latch circuit 83.

The comparator 81 compares the reference voltage RAMP input from the DAC 77 and an output value from the pixels 72 transmitted via the column signal line Vj connected to the comparator 81.

The counter unit 82 is DDR-driven on the basis of the double clock signal with a duty ratio of 50% input from the multiplying circuit 10 and counts time until comparison processing in the comparator 81 is completed. In the example shown in FIG. 3, the column ADC unit 80 is also caused to act as a CDS (Correlated Double Sampling) processing function unit. Therefore, up/down count processing in the counter unit 82 is controlled by the internal clock signal (a signal UD in FIG. 3) input from the timing control circuit 76.

The latch circuit 83 is driven by the internal clock signal (a signal LAT in FIG. 3) input from the timing control circuit 76 and stores count results (count values) of the counter unit 82. The count values stored by the latch circuit 83 are sequentially drawn out to a horizontal output line 84 by a scanning operation of the column scanning circuit 74.

As explained above, in the solid-state imaging device 70 according to this embodiment, the DAC 77 and the counter unit 82 are driven in the DDR system using the double clock signal with a duty ratio of 50% generated by the multiplying circuit 10 explained with reference to FIGS. 1 and 2. When the DAC 77 and the counter unit 82 are driven, the multiplying circuit 10 according to this embodiment can supply the double clock signal, a duty ratio of which is accurately adjusted to 50%, to the DAC 77 and the counter unit 82 irrespective of the frequency of the input internal clock. Therefore, in the solid-sate imaging device 70 according to this embodiment, operation margins of the DAC 77 and the counter unit 82 can be improved.

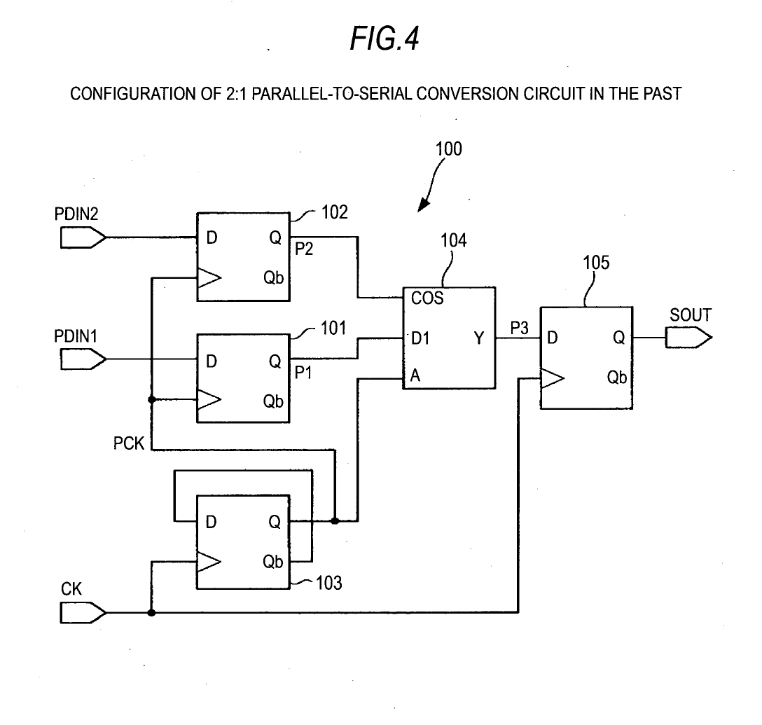

In the example explained in the embodiment, the multiplying circuit 10 explained with reference to FIGS. 1 and 2 is applied to the solid-state imaging device 70. However, the present invention is not limited to this and can be applied to an arbitrary electronic apparatus and an arbitrary electronic circuit that perform operation control using a clock signal with a duty ratio of 50%. For example, the multiplying circuit according to the embodiment may be applied to an interface circuit including the 2:1 parallel-to-serial conversion circuit 100 shown in FIG. 4. In this case, as in the case explained above, a clock signal, a duty ratio of which is highly accurately adjusted to 50%, can be stably supplied to the 2:1 parallel-to-serial conversion circuit 100. Therefore, a setup/hold margin of the 2:1 parallel-to-serial conversion circuit 100 can be maximized.

The present application contains subject matter related to those disclosed in Japanese Priority Patent Applications JP 2010-128621 and JP 2010-196145 filed in the Japan Patent Office on Jun. 4, 2010 and Sep. 1, 2010, respectively, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A clock multiplying circuit comprising:
a first inverter that is ON/OFF-controlled by a positive-phase signal of a first clock signal and includes a current source terminal and a current sync terminal for a control current flowing on an inside when the first inverter is on;
a second inverter that is ON/OFF-controlled by a negative-phase signal of the first clock signal and includes a current source terminal and a current sync terminal for a control current flowing on an inside when the second inverter is on, the current source terminal and the current sync terminal of the second inverter being respectively connected to the current source terminal and the current sync terminal of the first inverter;
a capacitive element provided between an output end of the first inverter and an output end of the second inverter;
a current supplying unit that increases, if a frequency of the first clock signal increases, the control current and supplies the control current to the current source terminals of the first inverter and the second inverter and outputs, from the current sync terminals of the first inverter and the second inverter, a control current having a current amount same as a current amount of the control current supplied to the current source terminal;
a differential detecting unit that receives input of a potential difference signal between both electrodes of the capacitive element and generates, on the basis of a comparison result in a median value of a fluctuation range of the potential difference signal, a second clock signal having a phase difference of 90 degrees with respect to the positive-phase signal of the first clock signal; and
a multiplied-signal generating unit that generates a double signal of the first clock signal on the basis of the first clock signal and the second clock signal.

2. The clock multiplying circuit according to claim 1, wherein the current supplying unit includes:
a current mirror circuit; and
a variable current source that supplies the control current to the first and second inverters via the current mirror circuit and, in supplying the control current, changes the control current according to the frequency of the first clock signal.

3. The clock multiplying circuit according to claim 1, wherein the differential detecting unit includes:
a differential comparator that generates, on the basis of the comparison result in the median value of the fluctuation range of the potential difference signal, a third clock signal having a phase difference of 90 degrees with respect to a negative-phase signal of the first clock signal; and
a third inverter that inverts the third clock signal generated by the differential comparator and generates the second clock signal.

4. The clock multiplying circuit according to claim 1, wherein the multiplied-signal generating unit is a logical circuit element that calculates exclusive OR of the positive-phase signal of the first clock signal and the second clock signal.

5. The clock multiplying circuit according to claim 1, further comprising an initializing switch element that sets the potential difference between both the electrodes of the capacitive element to zero.

6. The clock multiplying circuit according to claim 1, wherein
the first inverter includes
a P-type MOS transistor, a source terminal of which is connected to the current source terminal, a drain terminal of which is connected to one electrode of the capacitive element, and to a gate terminal of which the positive-phase signal of the first clock signal is input; and
an N-type MOS transistor, a source terminal of which is connected to the current sync terminal, a drain terminal of which is connected to one electrode of the capacitive element, and to a gate terminal of which the positive-phase signal of the first clock signal is input, and
the second inverter includes
a P-type MOS transistor, a source terminal of which is connected to the current source terminal, a drain terminal of which is connected to the other electrode of the capacitive element, and to a gate terminal of which the negative-phase signal of the first clock signal is input; and
an N-type MOS transistor, a source terminal of which is connected to the current sync terminal, a drain terminal of which is connected to the other electrode of the capacitive element, and to a gate terminal of which the negative-phase signal of the first clock signal is input.

7. A solid-state imaging device comprising:
plural pixels arranged in a matrix shape in a row direction and a column direction;
a clock multiplying circuit including
a first inverter that is ON/OFF-controlled by a positive-phase signal of a first clock signal and includes a current source terminal and a current sync terminal for a control current flowing on an inside when the first inverter is on, a second inverter that is ON/OFF-controlled by a negative-phase signal of the first clock signal and includes a current source terminal and a current sync terminal for a control current flowing on an inside when the second inverter is on, the current source terminal and the current sync terminal of the second inverter being respectively connected to the current source terminal and the current sync terminal of the first inverter,
a capacitive element provided between an output end of the first inverter and an output end of the second inverter,
a current supplying unit that increases, if a frequency of the first clock signal increases, the control current and supplies the control current to the current source terminals of the first inverter and the second inverter and outputs, from the current sync terminals of the first inverter and the second inverter, a control current having a current amount same as a current amount of the control current supplied to the current source terminal,
a differential detecting unit that receives input of a potential difference signal between both electrodes of the capacitive element and generates, on the basis of a comparison result in a median value of a fluctuation range of the potential difference signal, a second clock signal having a phase difference of 90 degrees with respect to the positive-phase signal of the first clock signal, and
a multiplied-signal generating unit that generates a double signal of the first clock signal on the basis of the first clock signal and the second clock signal;
a digital-to-analog conversion circuit that is driven by the double signal generated by the clock multiplying circuit and generates a reference voltage signal for analog to digital conversion; and
an analog-to-digital conversion circuit that includes a counter unit driven by the double signal generated by the clock multiplying circuit and converts a pixel value of the pixels into a digital value.

8. A phase-shift circuit comprising:
a first inverter that is ON/OFF-controlled by a positive-phase signal of a first clock signal and includes a current source terminal and a current sync terminal for a control current flowing on an inside when the first inverter is on;
a second inverter that is ON/OFF-controlled by a negative-phase signal of the first clock signal and includes a current source terminal and a current sync terminal for a control current flowing on an inside when the second inverter is on, the current source terminal and the current sync terminal of the second inverter being respectively connected to the current source terminal and the current sync terminal of the first inverter;
a capacitive element provided between an output end of the first inverter and an output end of the second inverter;
a current supplying unit that increases, if a frequency of the first clock signal increases, the control current and supplies the control current to the current source terminals of the first inverter and the second inverter and outputs, from the current sync terminals of the first inverter and the second inverter, a control current having a current amount same as a current amount of the control current supplied to the current source terminal; and
a differential detecting unit that receives input of a potential difference signal between both electrodes of the capacitive element and generates, on the basis of a comparison result in a median value of a fluctuation range of the potential difference signal, a second clock signal having a phase difference of 90 degrees with respect to the positive-phase signal of the first clock signal.
